(19) United States
(12) Patent Application Publication
(10) Pub. No.: US 2013/0196491 A1
(43) Pub. Date: Aug. 1, 2013

(54) METHOD OF PREVENTING DOPANT FROM DIFFUSING INTO ATMOSPHERE IN A BICMOS PROCESS

(71) Applicant: Shanghai Hua Hong Nec Electronics Co., Ltd., Shanghai (CN)

(72) Inventors: Donghua Liu, Shanghai (CN); Wenting Duan, Shanghai (CN); Jing Shi, Shanghai (CN); Wensheng Qian, Shanghai (CN); Jun Hu, Shanghai (CN)

(73) Assignee: SHANGHAI HUA HONG NEC ELECTRONICS CO., LTD., Shanghai (CN)

(21) Appl. No.: 13/753,983

(22) Filed: Jan. 30, 2013

(30) Foreign Application Priority Data
Jan. 31, 2012 (CN) 201210022022.9

(51) Int. Cl. H01L 21/265

(52) U.S. Cl. CPC H01L 21/265
USPC 438/524

(57) ABSTRACT

A method of preventing dopant from diffusing into atmosphere in a BiCMOS process is disclosed. The BiCMOS process includes the steps of: depositing a first silicon oxide layer and a silicon nitride layer over surface of a silicon substrate; etching the silicon substrate to form a plurality of shallow trenches therein; depositing a second silicon oxide layer over surface of the silicon substrate and forming silicon oxide sidewalls over inner side faces of each of the plurality of shallow trenches; forming a heavily doped pseudo buried layer under a bottom of one of the plurality of shallow trenches by implanting a dopant with a high concentration; performing an annealing process to promote diffusion of the dopant contained in the pseudo buried layer, wherein the method includes growing, by thermal oxidation, a silicon oxide layer over a bottom of each of the plurality of shallow trenches during the annealing process.

### CROSS-REFERENCES TO RELATED APPLICATIONS

This application claims the priority of Chinese patent application number 201210022022.9, filed on Jan. 31, 2012, the entire contents of which are incorporated herein by reference.

### TECHNICAL FIELD

The present invention relates to the fabrication of semiconductor integrated circuits, and more particularly, to a method of preventing a dopant from diffusing into an atmosphere in a bipolar complementary metal oxide semiconductor (BiCMOS) process.

### BACKGROUND

The applicant of this invention succeeded in reducing device area and cost by applying a self-developed deep-hole contact process and a pseudo buried layer process in a silicon-germanium (SiGe) bipolar complementary metal oxide semiconductor (BiCMOS) process. An exemplary BiCMOS process involving a pseudo buried layer process, which is developed and adopted by the applicant, is given by FIGS. 1(a)-1(c). The BiCMOS process includes the steps of:

1) depositing a first silicon oxide layer 102 and a silicon nitride hard mask layer 103 over the surface of a silicon substrate and etching the silicon substrate to form a plurality of shallow trenches 401 therein using the silicon nitride layer as an etch mask;

2) depositing a second silicon oxide layer 104 over the surface of the silicon substrate and forming silicon oxide sidewalls 105 over the inner side faces of each of the plurality of shallow trenches, wherein the silicon nitride layer 103 has a thickness of 300 Å to 1000 Å and the silicon oxide sidewalls 105 have a thickness of 200 Å to 1200 Å; and

3) forming a heavily doped P-type pseudo buried layer 106 under a bottom of one of the plurality of shallow trenches, e.g. the shallow trench on the right side in FIG. 1 (a), by implanting boron therein with a high concentration, wherein boron is implanted with a dose within the range of 1e14 cm⁻² to 1e16 cm⁻² and an energy within the range of 5 KeV to 50 KeV.

In these steps, as the silicon nitride layer 103 above the active region serves as a barrier, when the implantation is performed with an energy that is lower than a certain level, the dopant will not penetrate through the hard mask layer to enter the active region. Similarly, silicon oxide sidewalls 105 also prevent the dopant from entering the active region from either side face of any of the shallow trenches.

In order to enable the dopant in the P-type pseudo buried layer 106 to laterally diffuse into the active region, an annealing process must be used to promote the lateral diffusion of the dopant. For this reason, step 4) is further included in the aforementioned BiCMOS process to carry out an annealing process at a temperature of 950° C. for 30 minutes.

However, the inventors have found that during the annealing process, such diffusion of the dopant will also lead to the escape of boron atoms from the P-type pseudo buried layer 106 into the atmosphere, namely the chamber or furnace in which the substrate is disposed and processed. Moreover, as shown in FIG. 1 (b), the escaped boron atoms will enter non-doped or lightly doped N-type regions under other shallow trenches, e.g. the shallow trench on the left side in FIG. 1 (a), and forms an undesired P-type region 201 therein.

In such case, after all other subsequent device fabrication steps have been completed, including, for example, forming a heavily doped N-type pseudo buried layer 301 under a bottom of the shallow trench on the left side in FIG. 1 (a) by implanting phosphorus with a high concentration as an N-type dopant; forming a lightly doped region 501 that is connected with the N-type pseudo buried layer 301; and removing the silicon oxide sidewalls 105, the second silicon oxide layer 104, the silicon nitride layer 103 and the first silicon oxide layer 102, a device as shown in FIG. 1 (c) will be obtained, in which a P-type region 201 which will affect the performance of the device is present in a portion of the lightly doped region 501 near the bottom of the corresponding shallow trench.

### SUMMARY OF THE INVENTION

The present invention is to provide a method of preventing a dopant from diffusing into an atmosphere in a bipolar complementary metal oxide semiconductor (BiCMOS) process, which is capable of ensuring good performance of the silicon-germanium (SiGe) BiCMOS products fabricated.

To achieve the above objective, the present invention provides a method of preventing a dopant from diffusing into an atmosphere in a BiCMOS process, the BiCMOS process including the steps as follows: depositing a first silicon oxide layer and a silicon nitride layer over surface of a silicon substrate; etching the silicon substrate to form a plurality of shallow trenches therein; depositing a second silicon oxide layer over surface of the silicon substrate and forming silicon oxide sidewalls over inner side faces of each of the plurality of shallow trenches; forming a heavily doped pseudo buried layer under a bottom of one of the plurality of shallow trenches by implanting a dopant with a high concentration; and performing an annealing process to promote diffusion of the dopant contained in the pseudo buried layer, wherein the method includes growing, by thermal oxidation, a silicon oxide layer over a bottom of each of the plurality of shallow trenches during the annealing process.

The present invention grows, by mild oxidation, a silicon oxide layer over bottom of each of the shallow trenches during the annealing process, so as to form a relatively thick silicon oxide layer over bottom of the shallow trench where the heavily doped pseudo buried layer is formed and a relatively thin silicon oxide layer over bottoms of other shallow trenches, thus preventing a dopant contained in the heavily doped pseudo buried layer from diffusing into the atmosphere, and hence preventing the formation of undesired doped regions. This method will not affect subsequent implantation processes and is capable of ensuring good performance of the silicon-germanium (SiGe) BiCMOS products fabricated.

### BRIEF DESCRIPTION OF THE DRAWINGS

FIGS. 1(a)-1(c) are schematic diagrams showing a silicon-germanium (SiGe) bipolar complementary metal oxide semiconductor (BiCMOS) process adopted by the applicant of this invention.

FIGS. 2(a)-2(c) are schematic diagrams showing the method of preventing a dopant from diffusing into an atmosphere in a BiCMOS process according to an embodiment of the present invention.

### DETAILED DESCRIPTION

Further contents, characteristics and advantages of the present invention will emerge clearly from the ensuing description of example embodiments with reference to the accompanying drawings.

In order to prevent a dopant from diffusing into an atmosphere and hence to prevent the formation of undesired doped regions in a bipolar complementary metal oxide semiconductor (BiCMOS) process, the present invention modifies the BiCMOS process to include the steps as follows.

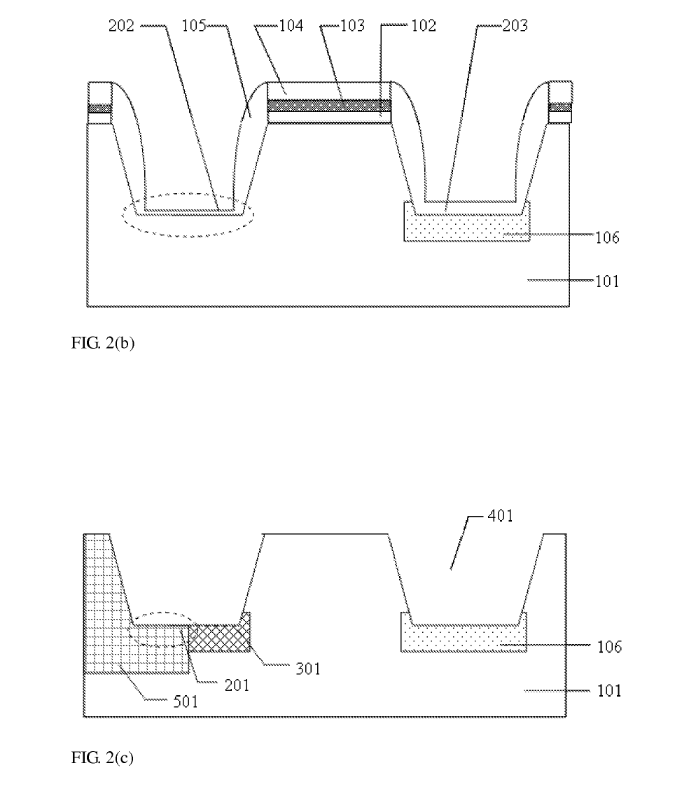

In a first step, as shown in FIG. 2 (a), a first silicon oxide layer 102 and a silicon nitride layer 103 are deposited over the surface of a silicon substrate 101 and the silicon substrate 101 is etched to form a plurality of shallow trench isolation (STI) structures 401 therein using the silicon nitride layer 103 as an etch mask. In this embodiment, the silicon substrate 101 is a P-type silicon substrate.

In a second step, as shown in FIG. 2 (a), a second silicon oxide layer 104 is deposited over the surface of the silicon nitride layer 103 and silicon oxide sidewalls 105 are formed over the inner side faces of each of the plurality of shallow trenches.

The silicon nitride layer 103 has a thickness of 300 Å to 1000 Å and the silicon oxide sidewalls 105 have a thickness of 200 Å to 1200 Å. Both of them serve to prevent, in the subsequent dopant implantation process, a dopant from entering an underlying active region.

In a third step, as shown in FIG. 2 (a), a heavily doped P-type pseudo buried layer 106 is formed under a bottom of one of the plurality of shallow trenches by implanting a dopant with a high concentration therein. In this embodiment, boron is implanted as the dopant under the shallow trench on the right side of the structure depicted by FIG. 2 (a) with a dose of 1e14 cm⁻² to 1e16 cm⁻² and an energy of 5 KeV to 50 KeV.

In a fourth step, an annealing process is carried out to promote the diffusion of the dopant contained in the pseudo buried layer 106, and at the same time, a thicker silicon oxide layer 203 is grown, by thermal oxidation, over the bottom of the shallow trench on the right side of the structure depicted by FIG. 2 (b) to prevent boron from diffusing into the atmosphere, and a thinner silicon oxide layer 202 is grown over the bottom of the other shallow trench on the left side of the structure.

Both the annealing and thermal oxidation processes are carried out at a temperature of 900° C. to 1000° C. for 30 minutes to 60 minutes.

Further, as the thickness of the silicon oxide layer 202 over the bottom of the other shallow trench is rather thin, it will not affect the subsequent implantation process.

After these steps, subsequent device fabrication steps are carried out to form a silicon-germanium (SiGe) BiCMOS device, including but not limited to the follows.

In a fifth step, a heavily doped N-type pseudo buried layer 301 is formed under a bottom of the shallow trench on the left side of the structure depicted by FIG. 2 (b) by implanting phosphorus with a high concentration as an N-type dopant.

In a sixth step, a lightly doped N-type region 501 that is in contact with the N-type pseudo buried layer 301 is formed in the silicon substrate 101.

Next, the silicon oxide sidewalls 105, the second silicon oxide layer 104, the silicon nitride layer 103 and the first silicon oxide layer 102 are all removed.

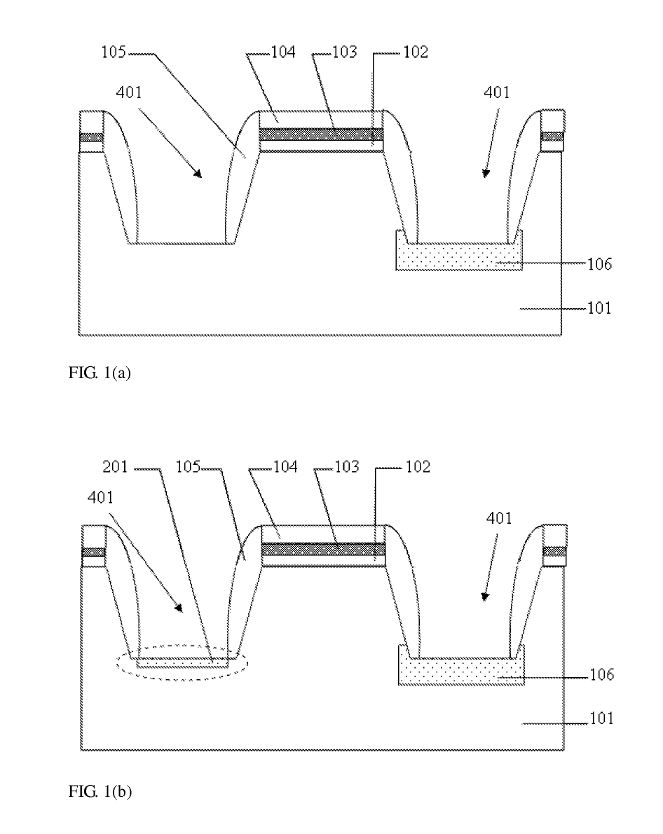

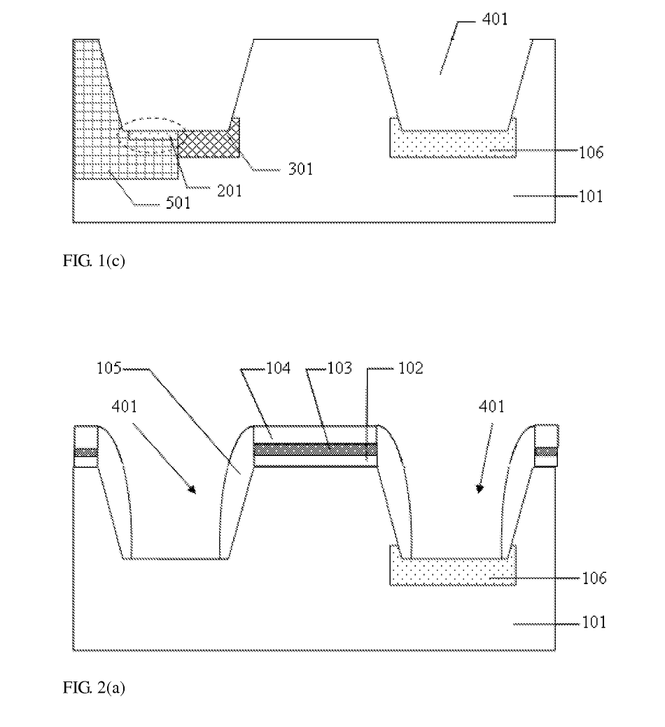

After the above steps, a device as shown in FIG. 2 (c) is obtained, which differs from the device shown in FIG. 1 (c) in that there is not such an undesired P-type region 201 formed in the portion of the lightly doped N-type region 501 near to the bottom surface of the shallow trench.

According to the foregoing description, the present invention grows, by mild oxidation, a silicon oxide layer over bottom of each of the shallow trenches during the annealing process, so as to form a relatively thick silicon oxide layer over bottom of the shallow trench where the heavily doped pseudo buried layer is formed and a relatively thin silicon oxide layer over bottoms of other shallow trenches, thus preventing a dopant contained in the heavily doped pseudo buried layer from diffusing into the atmosphere, and hence preventing the formation of undesired doped regions. This method will not affect subsequent implantation processes and is capable of ensuring good performance of the silicon-germanium (SiGe) BiCMOS products fabricated.

While specific embodiments have been presented in the foregoing description of the invention, they are not intended to limit the invention in any way. Those skilled in the art can make various modifications and variations without departing from the spirit or scope of the invention. Thus, it is intended that the present invention covers all such modifications and variations.

What is claimed is:

1. A method of preventing a dopant from diffusing into an atmosphere in a bipolar complementary metal oxide semiconductor (BiCMOS) process, the BiCMOS process including the steps of:
depositing a first silicon oxide layer and a silicon nitride layer over surface of a silicon substrate;
etching the silicon substrate to form a plurality of shallow trenches therein;
depositing a second silicon oxide layer over surface of the silicon substrate and forming silicon oxide sidewalls over inner side faces of each of the plurality of shallow trenches;
forming a heavily doped pseudo buried layer under a bottom of one of the plurality of shallow trenches by implanting a dopant with a high concentration; and
performing an annealing process to promote diffusion of the dopant contained in the pseudo buried layer,
wherein the method comprising growing, by thermal oxidation, a silicon oxide layer over a bottom of each of the plurality of shallow trenches during the annealing process.

2. The method according to claim 1, wherein the silicon oxide layer over the bottom of the one of the plurality of shallow trenches where the heavily doped pseudo buried layer is formed has a thickness greater than that of the silicon oxide layers over bottoms of the rest of the plurality of shallow trenches.

3. The method according to claim 1, wherein the silicon nitride layer has a thickness of 300 Å to 1000 Å and the silicon oxide sidewalls have a thickness of 200 Å to 1200 Å.

4. The method according to claim 1, wherein the dopant with a high concentration is boron.

5. The method according to claim 1, wherein the dopant with a high concentration is implanted at a dose of 1e14 cm⁻² to 1e16 cm⁻² with an energy of 5 KeV to 50 KeV.

6. The method according to claim 1, wherein the annealing process is carried out at a temperature of 900° C. to 1000° C. for 30 minutes to 60 minutes.

7. The method according to claim 1, wherein the thermal oxidation is carried out at a temperature of 900° C. to 1000° C. for 30 minutes to 60 minutes.
